(19) United States
(12) Patent Application Publication
(10) Pub. No.: US 2008/0251919 A1
(43) Pub. Date: Oct. 16, 2008

(54) Ultra-low resistance interconnect

(76) Inventors: Chien-Hsueh Shih, Taipei (TW); Shau-Lin Shue, Hsinchu (TW)

Correspondence Address: SLATER & MATSIL, L.L.P., 17950 PRESTON ROAD, SUITE 1000, DALLAS, TX, 75252, US

(21) Appl. No.: 11/786,527

(22) Filed: Apr. 12, 2007

(51) Int. Cl. H01L 23/532

(52) U.S. Cl. 257/751; 257/E23.154

(57) ABSTRACT

A method for fabricating a semiconductor interconnect device. A preferred embodiment comprises forming a low-k or very low-k dielectric layer on a wafer substrate and forming a recess in the dielectric layer that exposes a region on the substrate to which electrical contact is desired. A barrier layer is formed by first forming an organic layer on the walls of the substrate, then forming a catalyst metal layer on the organic layer, and finally forming a barrier metal layer over the catalyst layer. The remainder of the recess formed in the dielectric layer is then filled with a conductive material such as copper that will function as the main electrical connector to the contact region on the substrate.

### TECHNICAL FIELD

The present invention relates to semiconductor structures and fabricating methods used for integrated circuit devices, and more particularly to electrical interconnects used to connect one or more semiconductor-device active areas or other structures, and to a method of fabricating interconnects that is especially useful in very small semiconductor devices.

### BACKGROUND

Semiconductor devices are today used in a wide variety of applications; mobile phones, personal computers, and multimedia systems are just a few examples. The working core of devices such as these typically includes one or more chips, a chip being a packaged piece of semiconductor material upon which has been fabricated thousands, if not millions of very small electronic devices. These devices are interconnected to form integrated circuits that store and process electronic information so that the appliance is operable to perform its intended function. External connections are provided so that the integrated circuitry on a chip can be electrically coupled to a power source, one or more user interfaces, or to other semiconductor chips.

A semiconductor is a material, such as silicon, that may be treated with an impurity such as boron or phosphorus ions in a process called ion implantation, or doping. The resulting material will typically conduct electricity under certain conditions, such as the application of a small electrical charge. In order to put this property to use, various structures are fabricated into or on a thin slice of the semiconductor material called a wafer. These small structures may be formed of not only the semiconductor substrate itself, but also other insulating, conducting, and semiconducting materials that are formed onto the wafer substrate using a variety of methods. The materials that are added onto the substrate, and portions of the wafer substrate itself, may also be subject to selective removal. In this manner the many devices needed to create working integrated circuits.

A typical semiconductor wafer may range in size from six to twelve inches, although larger and smaller wafers are also known. A number of chips may be made from a single wafer, each using a small portion called a die. Dice may be as small as a quarter-inch or less, so a great many of them may be produced from a single wafer. Naturally, many of the fabrication operations such as the deposition or etching of materials are carried out for all of the dice on a wafer at about the same time, increasing productivity. The dice may or may not be intended for identical purposes. In any case, when all of the many fabrication stops have been completed the individual die are separated from each other and packaged in an encapsulation material after adding leads that will protrude from the package to make external electrical connections.

The individual electronic devices that are fabricated on the wafer, such as transistors and capacitors, are extremely small—as many as a million or more may be found on a single die. Needless to say, the processes and equipment for making such devices are very sophisticated. Advances in semiconductor manufacturing technology have, in fact, led to dramatic reduction in the size of the devices that are being made. This, of course, enables their use in smaller and smaller appliances—mobile telephones, for example, have gotten small enough to be easily carried in a shirt pocket. Moreover, there has been constant market demand for even smaller devices to make, for example, chips that fit into watches or small identification (ID) cards. This poses many challenges for manufacturers.

One small electronic device, for example, is called an interconnect. This interconnect is frequently used to connect together two or more other semiconductor devices or circuits. A metal, such as copper, is typically used as a conductor. Although not a complex device, because it must be able to translate electrical current over (relatively) significant distances without interfering with the operation of other nearby devices, the interconnect must be fabricated with a great deal of precision.

An exemplary interconnect is shown in FIGS. 1a and 1b. FIG. 1a is a cross-sectional side view of an exemplary interconnect 10. FIG. 1b is a cross-sectional view of interconnect 10 rotated 90° about a central vertical axis. In this example, interconnect 10 is used to electrically connect two active areas, 12 and 14, that have been formed in substrate 15. Note that the exact function of active areas 12 and 14 is not important to the present invention. They may, for example, be electrical circuits or devices such as those described generally above.

In any event, the purpose of interconnect 10 should be clear. The electrical connection between active areas formed on the same substrate level may not be achievable by a connector laid directly on or in the surface 16 of substrate 15. There may be other active areas in between, for example, or other conductive elements. Note in this regard that the configuration of FIG. 1 is highly simplified; there are typically a large number of active areas and interconnects in any semiconductor application. Note also that active areas and interconnects may be built on a number of levels, devices on different levels being separated by one or more layers of insulating materials.

Interconnect 10 includes a trench portion 20 and four via portions, three of which are visible in FIGS. 1a and 1b, and numbered 21 through 23. In fabrication the trench and via portions of interconnect 10 are formed by selective etching in a previously formed layer of dielectric material. Once formed, the trench and the vias are filled with a conductor such as copper. As should be apparent, this structure is used to electrically couple two or more active areas. It may also connect an active area to another interconnect or even two interconnects.

In some applications, forming the interconnect involves the formation of a barrier layer before the copper or other conductor material itself is deposited in order to prevent the conductor material's diffusion into the surrounding dielectric material. The barrier layer may, for example, include tantalum (Ta), tantalum nitride (TaN), titanium (Ti), or titanium nitride (TiN). A conductive seed layer may also be formed, over the barrier layer if a barrier layer is present, to insure that the copper conductor fully and securely fills the trench and vias. A seed layer may, for example, be useful when a copper conductor material is deposited into the interconnect using electrochemical plating (ECP). In some cases, the barrier layer may also act serve as a seed layer for deposition of the main body of conductive material.

As mentioned above, the size of all features in semiconductor devices, including interconnects, is getting smaller with each generation of new devices. Unfortunately, interconnect vias that are very small, for example those having critical dimensions of about 40 nm or less encounter difficulties with successful filling with conductor material, as illustrated in FIG. 2. FIG. 2 is a cross-sectional side view of a single via 30. Via 30 is a recess formed in a dielectric layer 37. Dielectric layer 37 overlies a substrate 39 on which a contact area 38 has been formed. Substrate 39 may be the base substrate wafer or some higher layer, created during fabrication. Contact area 38 is any portion of the semiconductor to which electrical contact is desired, for example an active area. Via 30 is, in this example, roughly cylindrical in shape and extends downward all the way to exposed contact area 38. Via 30 forms an opening 31, at which via 30 may join a trench (see FIGS. 1a and 1b) or some other structure (not shown in FIG. 2). In the example of FIG. 2, a barrier layer 35 has been formed on the sidewall 32 of via 30. Barrier layer 35 is typically formed using any one of a number of conventional methods such as plasma vapor deposition (PVD). As can be seen in FIG. 2, the barrier layer 35 created by this process tends to form an overhang 36 that significantly constricts opening 31. This may be an obstacle to proper formation of the seed layer or introduction of the main body of conductor material in the opening. In addition, barrier layer 35 forms an end portion 34 that covers contact area 38. The end portion 34 prevents direct contact between the main conductor material (not shown) and underlying substrate 39 and the contact area 38 formed there. It raises undesirably the via contact resistance (Rc). Needed then, is a way to form the underlying layers to ensure proper filling of very small interconnect vias with the conductive material that goes over them. The present invention provides just such a solution.

### SUMMARY OF THE INVENTION

These and other problems are generally solved or circumvented, and technical advantages are generally achieved, by preferred embodiments of the present invention, which are directed to a semiconductor device such as an interconnect that may be fabricated with very small dimensions and yet be successfully filled with conductive material and exhibit a low contact resistance (Rc).

In accordance with a preferred embodiment of the present invention, a method for fabricating a semiconductor device comprises forming a layer of dielectric material over a substrate or another device having an area to which an electrical connection is to be made, forming a via recess in the dielectric layer, forming a barrier layer on the walls of the via recess, and forming a conductive element in the recess such that the conductive area is coupled to, and is preferably directly in contact with the contact area and separated from the dielectric layer by the barrier layer. In a preferred embodiment, the barrier layer is formed by first forming a self-assembling monolayer (SAM) selectively on the via side wall, then forming a catalyst metal layer over the organic layer, and then forming a barrier metal layer over the catalyst layer.

In a preferred embodiment, the organic layer comprises an organosilane that forms the organic layer using chemisorption, the catalyst metal layer is formed by immersion of the organic layer in a solution of metal ions, and the barrier layer is formed by an electro-less (“E-less”) deposition procedure. The interconnect is then filled with a conductive material, such as copper introduced by electro plating, and finally the excess conductive material is removed using, for example, chemical mechanical polishing (CMP) to produce a planar surface on which further fabrication operations, if any, may be performed.

As more complete appreciation of the present invention and the scope thereof can be obtained from the accompanying drawings that are briefly summarized below, the following detailed description of the presently preferred embodiments of the present invention, and the appended claims.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1a is a cross-sectional side view of an exemplary interconnect. FIG. 1b is a cross-sectional view of the interconnect of FIG. 1a, rotated 90° about a central vertical axis.

FIG. 2 is a cross-sectional side view of a single exemplary via.

FIG. 3 is a flow diagram illustrating a method of fabricating a semiconductor device according to an embodiment of the present invention.

FIGS. 4a through 4e are a series of cross-sectional side views illustrating the configuration of an interconnect device at various selected stages of fabrication according to an embodiment of the present invention.

FIG. 5 is a cross-sectional side view illustrating a semiconductor device according to another embodiment of the present invention.

FIGS. 6a through 6c are simplified graphical representations of the process of forming a barrier layer according to an embodiment of the present invention.

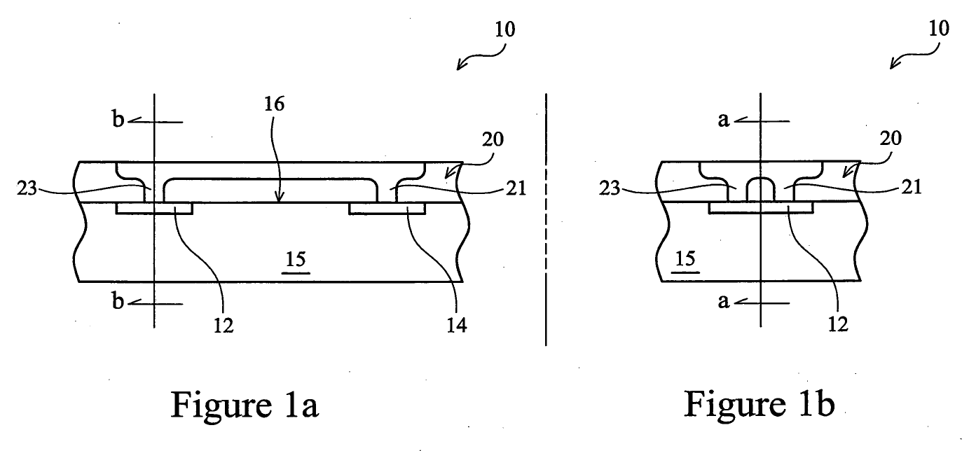

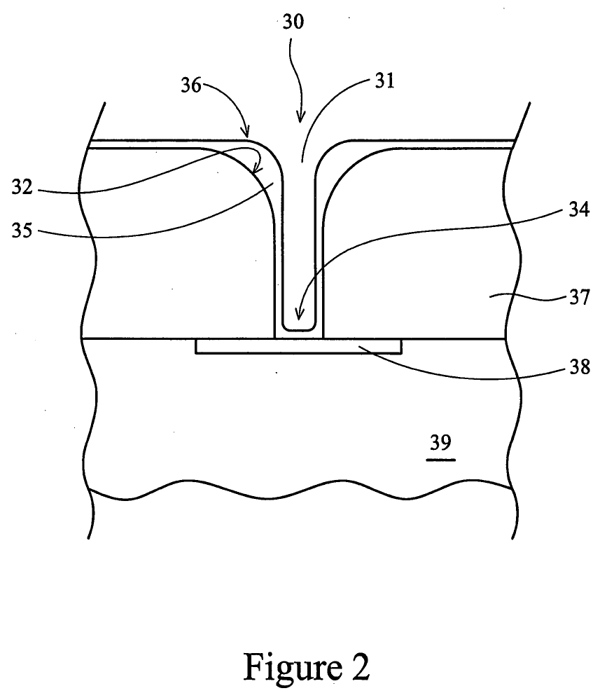

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely that of a single semiconductor interconnect via filled with a copper conductor. The invention may also be applied, however, to other structures and use other suitable materials as well. As mentioned above, the basic process for interconnect fabrication has drawbacks when vias or other similar structures of relatively-small dimensions are used. And as other semiconductor devices shrink, the use of these small interconnect vias becomes more and more necessary. The method of the present invention is well-suited to deal with these challenges. This method will now be described in more detail.

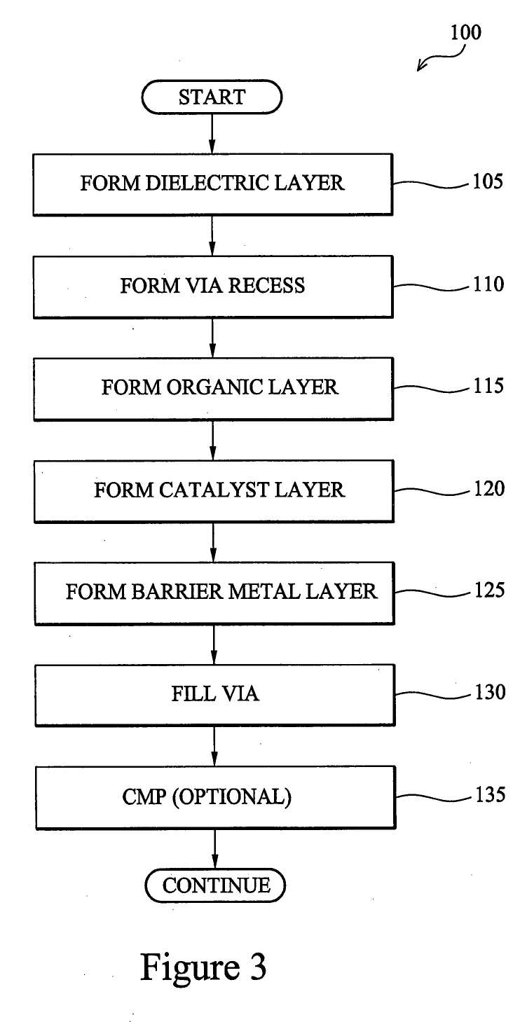

FIG. 3 is a flow diagram illustrating a method 100 of fabricating a semiconductor device according to an embodiment of the present invention. At START, it is again presumed that a contact area has been formed on a semiconductor substrate. Note again that these terms are used in their general sense; the contact area is simply a location on the substrate to which an electrical connection is desired, such as an active area, a contact pad, or another interconnect, and the substrate may refer either to the initially-used wafer of silicon or a similar material, or to whatever layer is exposed at this point in the fabrication process.

The method according to this embodiment begins with forming a dielectric layer (step 105). The dielectric layer generally covers the entire wafer being used for fabrication, although this is not necessarily the case. The dielectric layer is, however, preferably formed of a material having a low dielectric constant (“low-k”), and may even be ultra low-k. At least one via is then formed (step 110) as a recess in the dielectric layer, extending from the dielectric-layer surface. Of course, in most applications a great many vias will be formed (and filled) at the same time. With this understanding, the process will be described for convenience with reference to a single via. The via may, for example, be formed by patterning a photoresist layer on the surface of the dielectric layer and then etching away unprotected dielectric portions to form a recess extending from the dielectric-layer surface to the contact area. The photoresist is then removed (step not shown). If desired, a cleaning process may also be performed afterwards (also not shown).

According to the embodiment of FIG. 3, an organic layer is then formed (Step 115) on the side wall or walls of the via (again, using a single via as a representative for the process that will typically involve many). The organic layer preferably comprises an organosilane, for example 2-(trimethoxysily)-ethypyridine, N-(2-aminoethyl)-3-aminopropyltrimethoxy silane, 3-aminopropyltrimethoxy silane, or 3-aminopropyltriethoxy silane. Other suitable silanes may of course be used as well. In a preferred embodiment, the organic layer is formed as a monolayer by a selective self-assembling (SAM) process, preferably via chemisorption on the low-k dielectric.

A catalyst metal layer is then formed (step 120) on the organic layer. In a preferred embodiment, the catalyst metal layer is formed of one or more of cobalt (Co), palladium (Pd), and nickel (Ni), where the catalyst metal is present in a concentration of greater than about 95% atomic. In a preferred embodiment, the catalyst metal layer is formed by immersion adsorption, preferably using a solution including Pd or Co ions, or both.

After the formation of the catalyst metal layer, a barrier metal layer is formed in step 125. In one embodiment, the barrier metal layer is a cobalt alloy. In this case, the cobalt is preferably present in a concentration of less than about 96% atomic. The cobalt alloy may be formed, for example, using one or a combination of phosphorus, tungsten, rhenium, and molybdenum. In an alternate embodiment, the barrier metal layer is a nickel alloy, preferably present in a concentration of less than 95% atomic. In a preferred embodiment, the barrier metal layer is formed by electroless deposition.

After the formation of the barrier metal layer (step 125), the main conductive material may be added (step 130). Copper, for example, may be used as the main conductive material and deposited using sputtering or ECP. If necessary, as is often the case, CMP may be performed (step 135) to planarize the surface and remove any conductor material in undesirable locations.

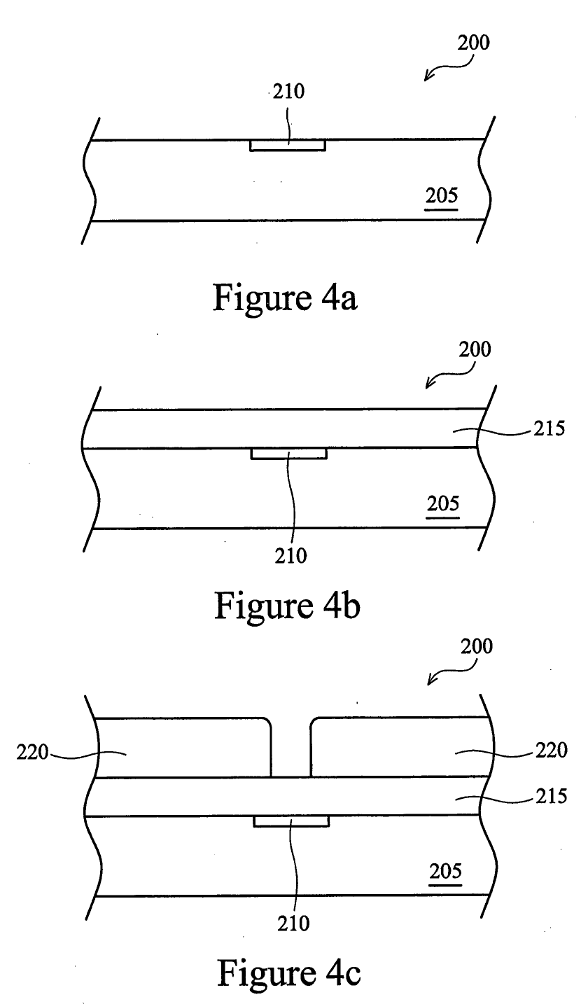

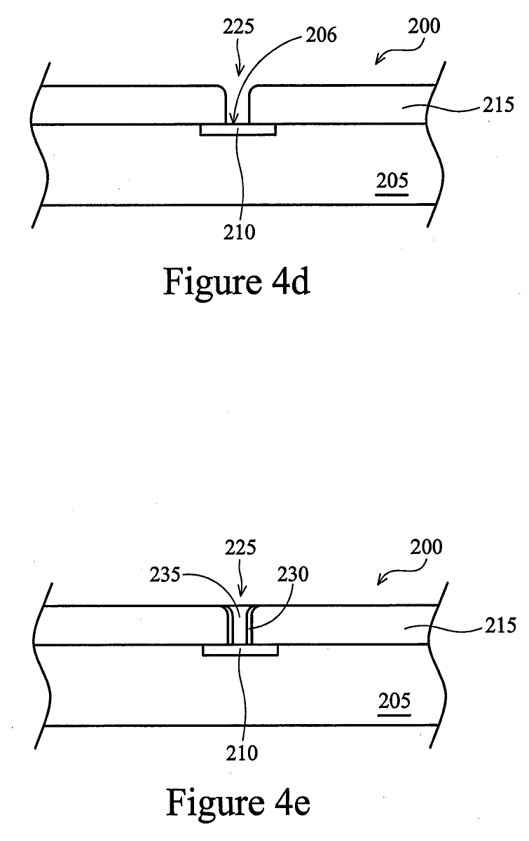

FIGS. 4a through 4e are a series of cross-sectional side views illustrating the configuration of an interconnect device 200 at various selected stages of fabrication according to an embodiment of the present invention. FIG. 4a illustrates a substrate 205 onto which a contact area 210 has been formed. Again, no specific nature of this contact area is required. A dielectric layer 215 is then formed over the substrate 205 and contact area 210, as shown in FIG. 4b.

According to this embodiment of the present invention, to form the via a layer of photoresist 220 is formed over the dielectric layer 215 and then patterned. Patterning involves exposing the photoresist to light, which alters its physical characteristics so that certain portions may be removed by an appropriate solvent. A device having a patterned photoresist layer is illustrated in FIG. 4c. The unprotected portion of the dielectric layer 215 is then etched away, followed by removal of the remaining photoresist layer. The result is a via 225, or recess, extending down to the contact area 210, as can be seen in FIG. 4d.

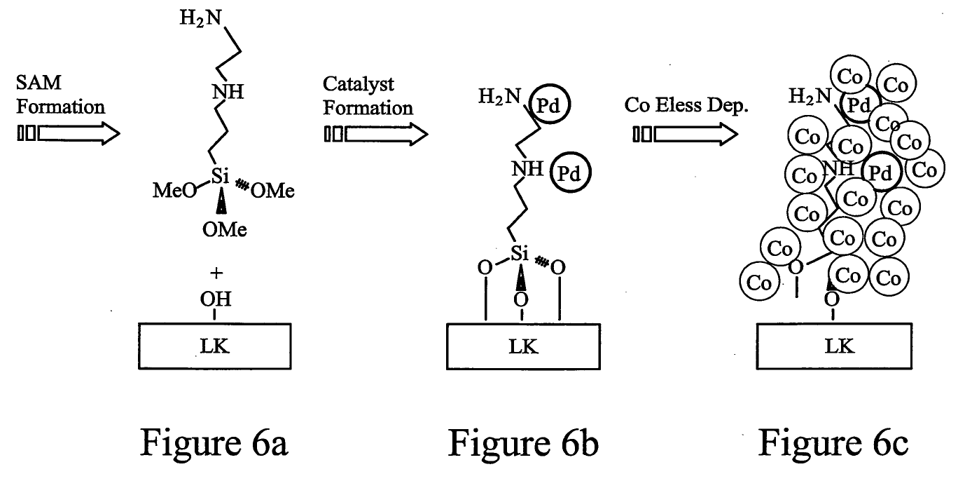

In accordance with the present invention, a selective, conformal layer is then formed in preparation for finishing the interconnect. As described above, in one embodiment, this begins with the formation of a self-assembling (SAM) organic monolayer, preferably using chemisorption where organosilane molecules bond with hydroxyl ions present at the low-k dielectric portion of the via recess 225. A graphic illustration of this chemisorption process according to one embodiment of the present invention is presented in FIG. 6a. Note that in FIGS. 6a through 6c, the low-k dielectric layer is labeled simply “LK”. As should be apparent, however, the organosilane will preferably not bond with the materials of the substrate 205 at the lower end of via 225, preventing the formation of a barrier layer there. That is, the surface of the contact area 210 is substantially free of barrier-layer formation in preparation for the following process step, in which the main conductive material directly contacts the surface 206 of contact area 210. This configuration reduces via contact resistance in interconnection. (Note that in some embodiments, the barrier layer may come into contact with the exposed surface of the contact layer at its periphery near the sidewall. Such contact, if any, leaves the surface 206 substantially exposed.)

A catalyst metal layer is then formed, preferably by immersion of the organic layer material into a solution including catalyst metal ions, preferably Pd, Co, or both. A graphic illustration of this immersion process according to one embodiment of the present invention is presented in FIG. 6b. In this embodiment, Pd²⁺⁺ ions are shown bonding with the existing organic layer. Finally, the barrier metal layer is formed on the catalyst layer, preferably by electroless (“E-less”) deposition. A graphic illustration of this E-less process according to one embodiment of the present invention is presented in FIG. 6c. In the process of the illustrated embodiment, the barrier metal layer is a Co layer. The resulting configuration is a completed interconnect device 200, as illustrated in FIG. 4e. Note that only the via 225 portion of the interconnect device 200 is, for simplicity, shown in FIG. 4e, where via 225 can be seen filled with a copper (Cu) conductive material 235, which is separated from the dielectric layer 215 (but not the substrate 205 or contact area 210) by a barrier 230.

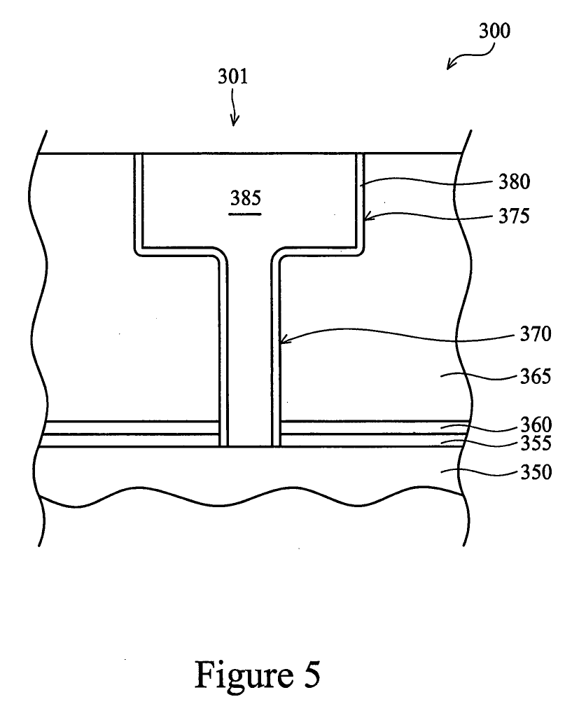

A more complete interconnect structure is illustrated in FIG. 5. FIG. 5 is a cross-sectional side view illustrating a semiconductor device 300 according to another embodiment of the present invention. Interconnect device 300, in this embodiment, includes an interconnect 301 that is substantially formed of a trench 375 portion and a via portion 370, the latter extending from trench 375 all of the way down to the Cu conductive material of another interconnect device 350. In the embodiment of FIG. 5, a Co capping layer 355 has been formed above the interconnect 350, and an etch stop layer 360 has been formed above the Co capping layer 355. A low-k dialectic layer 365 has been formed over the etch stop layer 360.

The low-k dielectric layer may, in one embodiment, be form as a film by the Black Diamond method provided by Applied Materials of Santa Clara Calif. The low-k dielectric layer 365 forms the recess including both via 370 and trench 375. Interconnect 301, including both trench 375 and via 370, is filled with a conductive material 385, such as Cu, which is separated from the dielectric layer 365 by a barrier layer 380. In a preferred embodiment, the barrier layer 380 includes an organic layer, a catalyst layer, and a barrier metal layer (not separately shown). In many cases, the co-planarity of the top surfaces of dielectric layer 365, barrier layer 380, and Cu conductor 385 is achieved using a chemical metal polishing (CMP) or similar process.

Although the present invention and its advantages have been described in detail, it should be understood that various changes, substitutions and alterations can be made herein without departing from the spirit and scope of the invention as defined by the appended claims. For example, the interconnect may be differently configured, or some other semiconductor device may be fabricated according to the present invention. Different materials may also be used in substitution for those recited above.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An interconnect for use in a semiconductor device, comprising:
an organic layer formed on a side wall of a recess;
a catalyst metal layer formed on the organic layer; and
a barrier metal layer formed on the catalyst metal layer.

2. The interconnect of claim 1, wherein the recess is formed in a dielectric layer.

3. The interconnect of claim 1 wherein the organic layer comprises an organosilane.

4. The interconnect of claim 1, wherein the organic layer comprises 3 aminopropyltrimethoxy silane.

5. The interconnect of claim 1, wherein the organic layer comprises 3 aminopropyltriethoxy silane.

6. The interconnect of claim 1, wherein the organic layer comprises N-(2-aminoethyl)-3-aminopropyltrimethoxy silane.

7. The interconnect of claim 1, wherein the organic layer comprises 2-(trimethoxysily)-ethypyridine.

8. The interconnect of claim 1, wherein the catalyst metal layer comprises palladium.

9. The interconnect of claim 1, wherein the catalyst metal layer comprises cobalt.

10. The interconnect of claim 1, wherein the catalyst metal layer comprises nickel.

11. The interconnect of claim 1, wherein the catalyst metal is present in a concentration greater than about 95%.

12. The interconnect of claim 1, wherein the barrier metal comprises a nickel alloy.

13. The interconnect of claim 12, wherein the nickel alloy comprises phosphorus.

14. The interconnect of claim 1, wherein the recess is formed so as to expose a surface of a contact area, and wherein the organic layer, the catalyst layer, and the barrier metal layer are all formed such that the surface of the contact area remains substantially exposed.

15. A semiconductor device, comprising:
a contact area;
a dielectric layer formed above the contact area, the dielectric layer forming a recess having a side wall, the recess exposing at least a portion of the contact area; and
a conformal layer covering substantially all of the recess side wall, the conformal layer comprising an organic layer.

16. The semiconductor device of claim 15, further comprising a catalyst metal layer formed on the organic layer.

17. The semiconductor device of claim 16, further comprising a barrier metal layer formed on the catalyst metal layer.

18. The semiconductor device of claim 18, further comprising a main conductive element filling the recess, wherein the main conductive element directly contacts the contact area.

19. The semiconductor device of claim 15, wherein the dielectric layer is formed of a low-k dielectric.

20. A semiconductor device interconnect, comprising a main conductive element filling a dielectric-layer recess and in communication with a contact area adjacent to the dielectric layer, wherein a conformal layer comprising an organic layer, a catalyst metal layer is interposed between the dielectric layer and the main conductive element.
